(19) United States
(12) Patent Application Publication
(10) Pub. No.: US 2010/0295571 A1
(43) Pub. Date: Nov. 25, 2010

(54) Device and Method for Configuring a Semiconductor Circuit

(76) Inventors: Reinhard Weiberle, Vaihingen/Enz (DE); Bernd Mueller, Leonberg-Silberberg (DE); Eberhard Boehl, Reutlingen (DE); Yorck von Collani, Beilstein (DE); Rainer Gmehlich, Ditzingen (DE)

Correspondence Address: KENYON & KENYON LLP, ONE BROADWAY, NEW YORK, NY, 10004, US

(21) Appl. No.: 11/990,095

(22) PCT Filed: Jul. 27, 2006
(86) PCT No.: PCT/EP2006/064751

§ 371 Date: Jul. 13, 2010

(30) Foreign Application Priority Data
Aug. 8, 2005 (DE) 10 2005 037 236.8

(51) Int. Cl. G01R 31/00; H01L 21/66

(52) U.S. Cl. 324/759.01; 438/14; 257/E21.521

(57) ABSTRACT

A device and method for configuring a semiconductor circuit having at least two identical or similar functional units, the faulty unit being identified and deactivated if an error occurs in at least one of the identical or similar functional units.

### BACKGROUND INFORMATION

The manufacture of complex semiconductor structural elements such as microcontrollers (μC) or also ASICs is prone to errors. Since doping is a statistical process for structure sizes that are becoming smaller and smaller, errors in manufacturing are unavoidable even in the long term. It is even becoming apparent that the susceptibility to errors will increase in the future, despite major efforts and advances. The yield, that is, the ratio of correctly operating structural elements to the number of manufactured components, is approximately 90% for a mastered manufacturing process (that is, even in this instance 10% is already waste); however, it is quite possible that much lower values occur. Mechanisms for increasing the yield thus bring about a direct decrease in costs. Furthermore, as a result of considerations related to testing and manufacturing, there is an increasing demand for the ability to handle faulty structural elements in the field.

One way that is already partially implemented today for tolerating, in operation, errors that occurred in the manufacturing of memory components like Flash, RAM, or ROM is the use of an error correcting code. In it, check bits are stored in addition to data bits. The check bits are such that when just one bit is corrupted (or a known maximum number of bits), the error may be detected and corrected by an additional logic. This has the effect that the entire structural element (or the relevant subcomponent of a structural element) provides a correct result even when errors are present. Storing the check bits requires a significant additional expenditure, while the necessary additional logic creates practically no great additional costs.

Errors in semiconductor circuits, in particular in computer systems, may also occur when these circuits are in operation. In most cases it is not possible to guarantee a high operational availability in systematic form also in the event of permanent errors. ECC mechanisms for memories are one of the few exceptions. Recovery or reset measures are known for transient errors in processors, in particular CPUs. However, no realistic cost-effective concept for tolerating permanent errors is known for errors in execution units.

One objective of the present invention is to improve the yield in the manufacturing process of μCs or semiconductor structural elements, in particular by making it possible to use components having faulty functional units. A second objective of the present invention is to increase the availability of structural elements in operation. To this end, means are to be provided that make it possible to identify faulty execution units (e.g., cores, ALU, processors) in a structural element, and that enable a “graceful degradation” or an emergency operating mode when operating a system that uses this component.

### SUMMARY

A semiconductor circuit, for example, a μC, that contains at least two identical or similar functional units is considered. A test program identifies potentially faulty functional units at the end of the production process, during installation, during diagnosis, or in test phases in operation. This may be carried out advantageously by a switchover and compare function, illustrated, for example, in a switchover and compare unit, that compares the output signals of one functional unit to the output signals of at least one additional functional unit and/or to additional reference values. The information as to which functional units are faulty is stored in a memory element. These functional units are deactivated, for example, by the switchover and compare unit or by an interruption device. The structural component is usable and functional even though it contains faulty functional units.

A method for configuring a semiconductor circuit having at least two identical or similar functional units is advantageously described, wherein when an error occurs in at least one of the identical or similar functional units, the faulty unit is identified and deactivated.

A method is advantageously described, wherein the configuration of the semiconductor circuit takes place as a process step of a manufacturing, test, diagnosis, or maintenance process.

A method is advantageously described, wherein in each case at least two of the identical or similar functional units of the semiconductor circuit are able to be switched into an operating mode in which these functional units execute identical functions, instructions, program segments, or programs, and a comparison of the output signals of these functional units is possible.

A method is advantageously described, wherein faulty functional units are identified in that output signals of these functional units are compared to reference values.

A method is advantageously described, wherein the initiation of the switchover and/or the reciprocal comparison of the output signals of at least two functional units and/or the comparison of output signals to reference values may be performed by external manufacturing, test, or diagnosis devices that are not part of the semiconductor circuit.

A method is advantageously described, wherein a configuration status and/or error status is formed for at least the functional units of the semiconductor circuit that are identified as faulty.

A method is advantageously described wherein a functional unit is deactivated in that information about the configuration status or the error status of this functional unit is stored in a memory device such that it may be read out when the semiconductor system is being initialized and/or operated, and the stored information is processed such that in operation a use the unit labeled as faulty is not allowed.

A method is advantageously described, wherein external manufacturing, test, or diagnosis devices that are not part of the semiconductor circuit may ascertain the configuration status or the error status of at least one functional unit of the semiconductor circuit and/or store this information in a memory device.

A method is advantageously described, wherein a unit that is identified as faulty is deactivated in an irreversible manner.

A method is advantageously described, wherein electrical connections to or between functional units of the semiconductor circuits are interrupted.

A method is advantageously described, wherein electrical connections on the semiconductor circuit are interrupted by mechanical action on the semiconductor circuit.

A method is advantageously described, wherein electrical connections on the semiconductor circuit are interrupted by chemical action on the semiconductor circuit.

A method is advantageously described, wherein electrical connections on the semiconductor circuit are interrupted by optical action on the semiconductor circuit.

A method is advantageously described, wherein electrical connections on the semiconductor circuit are interrupted by electrical action on the semiconductor circuit.

A method is advantageously described, wherein a functional unit is deactivated by external manufacturing, test, or diagnosis devices.

A device for configuring a semiconductor circuit having at least two identical or similar functional units is advantageously described, wherein an arrangement exists for identifying an error in at least one of the identical or similar functional units, and for deactivating the faulty unit.

A device is advantageously included, wherein a switchover element exists with which at least two of the identical or similar functional units of the semiconductor circuit may be switched over into an operating mode in which these functional units execute identical functions, instructions, program segments, or programs.

A device is advantageously included, wherein a comparitor exists with which a comparison of the output signals of at least two functional units is possible.

A device is advantageously included, wherein a comparitor exists with which a comparison of the output signals of at least one functional unit to reference values is possible.

A device is advantageously included, wherein a storage element exists in which reference values are stored for identifying faulty functional units.

A device is advantageously included, wherein the comparitor and/or memory exist at least partially on the semiconductor circuit.

A device is advantageously included, wherein a reception device exists on the semiconductor circuit with which signals from manufacturing, test, diagnosis, and maintenance devices may be received.

A device is advantageously included, wherein a storage device for storing data exist in which at least one item of information about the configuration status or the error status of functional units may be stored in such a way that it may be read out when the semiconductor system is being initialized or and/or operated.

A device is advantageously included, wherein an element exists that is able to read out and process memory information and as a function of the memory information are able to permit or prevent in operation a use of the unit labeled as faulty.

A device is advantageously included, wherein the element for storing data is a non-volatile memory device.

A device is advantageously included, wherein the memory is designed such that a write access to the memory may be carried out only by manufacturing, test, diagnosis, and maintenance devices that are not installed on the semiconductor circuit.

A device is advantageously included, wherein a switchover element for the reversible deactivation of a functional unit exist, and this device is part of the semiconductor circuit or part of the structural element on which the semiconductor circuit is implemented.

A device is advantageously included, wherein an element exists to irreversibly deactivate a functional unit.

### BRIEF DESCRIPTION OF THE DRAWINGS

FIG. 1 shows a general switchover component having a switching circuit logic and processing logic.

FIG. 2 shows the connection of the switchover component to a memory element.

FIG. 3 shows a fundamental method for increasing yield when using a memory element.

FIG. 4 shows a fundamental method for increasing operational availability, graceful degradation, and emergency operation.

FIG. 5 shows the connection of the switchover component to an influencing component.

FIG. 6 shows a fundamental method for increasing yield when using an influencing component.

FIG. 7 shows the design of a possible memory element.

### DETAILED DESCRIPTION OF EXAMPLE EMBODIMENTS

In the following, an execution unit may denote both a processor/core/CPU, as well as an FPU (floating point unit), a DSP (digital signal processor), a co-processor or an ALU (arithmetic logical unit).

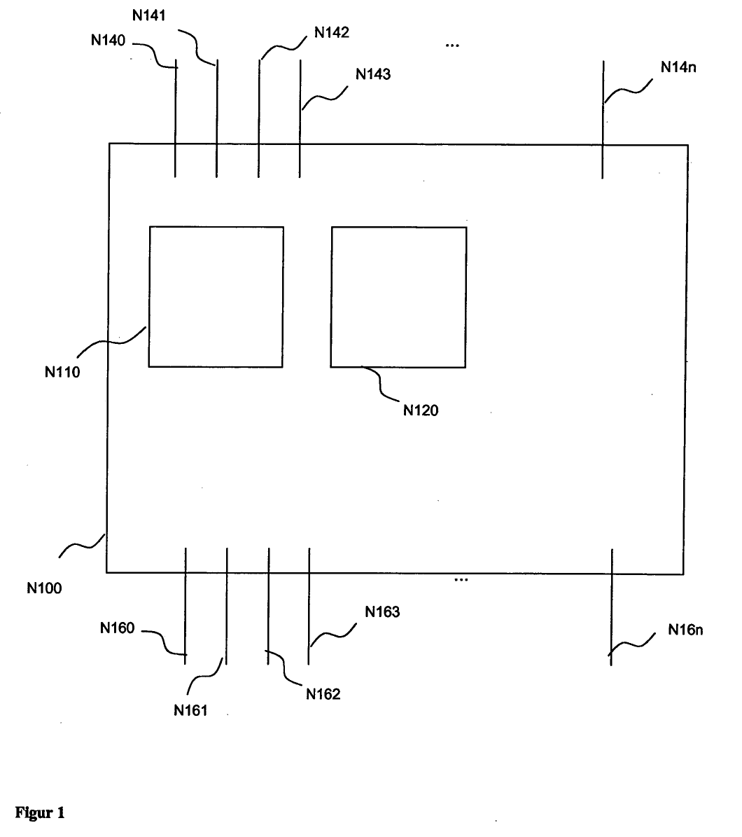

FIG. 1 first shows a general case of the switchover and compare unit, which may be used even with more than two execution units. Of the n execution units to be considered, n signals N140, . . . , N14n are transmitted to switchover and compare component N100. From these input signals, this component is able to generate up to n output signals N160, . . . , N16n. In the simplest case, the “pure performance mode,” all signals N14i are routed to the corresponding output signals N16i. In the opposite, limiting case, the “pure compare mode,” all signals N140, . . . , N14n are routed only to precisely one of output signals N16i.

This figure illustrates how various possible modes may be produced. To this end, N100 includes the logic component of a switching circuit logic N110. It is first the task of the switching circuit logic to establish which inputs are not switched to any output, that is, which inputs are ignored, remain without consequences, or are inactive. In the following, this function of the switching circuit logic is also often referred to as the first function of the switching circuit logic. Additionally, switching circuit logic N110 establishes how many output signals exist overall and which of the input signals contribute to which of the output signals. In this context, one input signal may contribute at most to precisely one output signal. In the following, this function of the switching circuit logic is also often referred to as the second function of the switching circuit logic.

Formulated differently in mathematical form, without blocking signals, the switching circuit logic thus defines a function that assigns one element of set {N160, . . . , N16n} to each element of set {N140, . . . , N14n}. More generally, when blocking individual input signals, the switching circuit logic defines a function that assigns one element of set {N160, . . . , N16n} to each element of an established subset of {N140, . . . , N14n} (the signals that are not blocked).

For each of outputs N16i, processing logic N120 then establishes the form in which the inputs contribute to this output signal. To describe the different possible variations by way of example, let it be assumed, without limiting the universality, that output N160 is generated by signals N141, . . . , N14m. If m=1, this simply corresponds to the signal being switched through; if m=2, then signals N141, N142 are compared. This comparison may be performed synchronously or asynchronously; it may be performed on a bit-by-bit basis, or only for significant bits or also using a tolerance range. A preferred option is that execution units run in a lockstep operation (that is, identical instructions run with the same frequency). However, a fixed clock pulse offset or phase offset is also an advantageous solution.

In the case that m>=3, a plurality of options exists.

One first option is to compare all of the signals, and, if at least two different values exist, to detect an error that may optionally be signaled.

A second option is to make a k-out-of-m selection (k>m/2). This option may be implemented by using comparators. An error signal may be optionally generated if one of the signals is recognized as deviant. A possibly differing error signal may be generated if all three signals are different.

A third option is to supply these values to an algorithm. This may take the form of generating an average value, a median value, or of using a fault-tolerant algorithm (FTA), for example. Such an FTA is based on discarding extreme values of the input values, and performing a type of averaging of the remaining values. This averaging may be performed for the entire set of the remaining values or preferably for a subset that is easily formed in hardware. In this case, it is not always necessary to actually compare the values. For example, in the averaging operation, it may merely be necessary to add and divide; FTM, FTA or median require a partial sorting. If appropriate, an error signal may optionally be output here as well, given sufficiently high extreme values.

For the sake of brevity, these various mentioned options for processing a plurality of signals to form one signal are referred to as comparison operations. Thus, the task of the processing logic is to establish the exact form of the comparison operation for each output signal, and thus also for the corresponding input signals. In the following, this task is referred to as the second function of the processing logic. In the following, the identification of faulty execution units that is thereby normally possible is referred to as the first function of the processing logic.

The combination of the information of switching circuit logic N110 (i.e., the function mentioned above) and of the processing logic (i.e., the establishment of the comparison operation per output signal, i.e., per functional value) is the mode information, and this information establishes the mode. In the general case, this information is naturally multi-valued, i.e., not representable by only one logic bit. Not all theoretically possible modes are practical in a given implementation; preferably, the number of permitted modes will be limited. Note that, in the case of only two execution units, where there is only one compare mode, the entire information may be condensed into only one logic bit.

A switch from a performance mode to a compare mode is generally characterized by the fact that execution units, which are mapped to different outputs in the performance mode, are mapped to the same output in the compare mode. This is preferably implemented by providing a subsystem of execution units, in which in the performance mode all input signals N14i, which are to be considered in the subsystem, are directly switched to corresponding output signals N16i, while in the compare mode they are all mapped to one output. Alternatively, such a switchover operation may also be implemented by altering pairings. This demonstrates that it is generally not possible to speak of the performance mode and the compare mode, although, in a given embodiment of the present invention, the set of permitted modes may be limited in such a way that this is the case. However, it is always possible to speak of a switch from performance mode to compare mode (and vice versa).

The following describes how under certain conditions it is possible to increase the yield in the manufacturing process of semiconductor structural elements, e.g., AC, with the aid of such a switchover and compare component and some other elements.

The following roughly outlines the basic idea:

The structural element, for example a μC, has more execution units than are required in operation.

Thus, it is also possible to operate with fewer than the complete number of correctly operating execution units. The prerequisite for this is that incorrectly operating units are identified and are not able to have any effects on the overall system. The use of a switchover and compare unit described above makes it possible to use switching circuit logic N110 to prevent the signals of faulty execution units from being spread further in the system.

Processing logic N120 makes it possible to compare signals of different execution units. It is possible to identify faulty execution units through a suitable comparison. This is possible if a test program is used that covers errors sufficiently. Where necessary, it is also possible to use additionally external means for identification.

Because such a test is executed at some point in time, for example, at the end of the assembly line, at the time of initialization, or during installation, and the result (that is, a definite identification of the faulty execution units) is stored in a preferably non-volatile memory, and because this result influences the switching circuit logic N110 such that the signals of faulty execution units have no effect, a μC is obtained whose correctly operating execution units may still be used, even if faulty execution units exist.

The error tolerance achieved in this way in the product makes it possible to increase the yield, since in this way even faulty structural elements may be used, as long as the number of still correctly operating execution units is large enough. This depends on the application.

This idea will now be described in more detail.

One possible logical design of the switchover and compare unit is described above. For the application of the present invention described here, it is indeed advantageous, but not necessary, for the component to exist as such and for the named subcomponents, the switching circuit logic and the processing logic, to exist.

For the first function of the switching circuit logic, outputs of potentially faulty components are able to be ignored in a suitable form. This may be achieved by interrupting these outputs by switches, for example. Another option is to switch the outputs to a standard “collector” for faulty signals. Another option is to mark the output signals as invalid. Still another option that may be implemented additionally or alternatively to this is to prevent the occurrence of such output signals in that the relevant component itself is deactivated. This, in turn, may be achieved by deactivating the component, by halting, by interrupting the clock pulse, or by interrupting the input signals. This also has the advantage that the power loss is minimized and thus lifetime, reliability, and temperature load are optimized. In the following, all execution units whose output may be ignored by some means are referred to as passive or inactive.

For the first function of the processing logic, it is first of all crucial that a faulty component is able to be identified. A preferred option is to permit all execution units to execute the same program in parallel. Preferably, but not necessarily, this is able to be implemented in that the execution units are operated in a lockstep mode or also at a fixed clock-pulse offset or phase offset. Thus, a suitable comparison makes it possible to identify a potentially present faulty component via a voter-basis decision. Optionally, in a test in production, initialization, or at the end of the assembly line, additionally the results of this program may be compared to the previously known results by an external unit (watchdog, another μC, test device, ASIC). This is advantageous particularly if only two execution units exist, since if this is the case, when a difference between two execution units occurs, a third item of information is required for identifying the faulty execution unit. In addition to being implemented through the comparison operations described above, such a comparison may also be implemented such that it is performed only for pairs or on subsets, until a definite identification of potentially faulty execution units is possible. Thus, the processing logic must identify the faulty components as a result of this first function.

The test program should be designed such that an error is most likely to have an effect. For example, an error model (for example, stuck-at model) may be used, a part of the application code may executed, or a complete instruction test may be used for the development of such a program. In the case of the test at the end of the assembly line, this may correspond to a current test program that is restricted to the execution units. However, it is also possible to combine this with an end-of-assembly line test that is common today, and use this program to test only those structural elements that already failed in the first end-of-assembly line test. The particular advantage of this last procedure is that only those structural elements that would otherwise be rejected are subjected to an additional process step. Each structural element obtained by this last “saving step” directly increases the yield of the manufacturing process.

Once the first function of the processing logic has identified the faulty units, this information must be stored. Preferably, a non-volatile memory element is used when applying the method according to the present invention to the manufacturing process to increase the yield. It then stores which execution units are inactive.

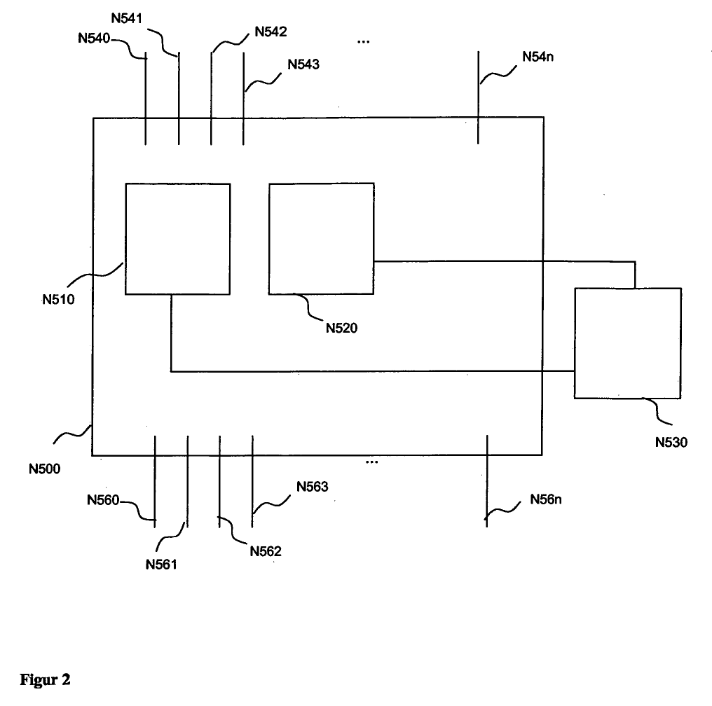

FIG. 2 shows the function of this memory element. In FIG. 2, elements N510, N520, N54i, N56i of the switchover and compare unit N500 have the same functions as the elements N110, N120, N14i, N16i of the switchover and compare unit N100 in FIG. 1. A memory element N530 is also shown. Processing logic N520 sends to memory element N530 the information about the execution units identified as faulty. Switching circuit logic N510 is able to access memory element N530 and perform the first function of the switching circuit logic such that the elements labeled as inactive by N530 actually become inactive.

Of course, the memory element may lie within the switchover and compare unit; however, it may also lie outside of it—even outside of the structural element. For example, an external element is conceivable when installing a μC in a control device or a PC, since in that instance a more extensive test using the peripheral unit may also possibly be used.

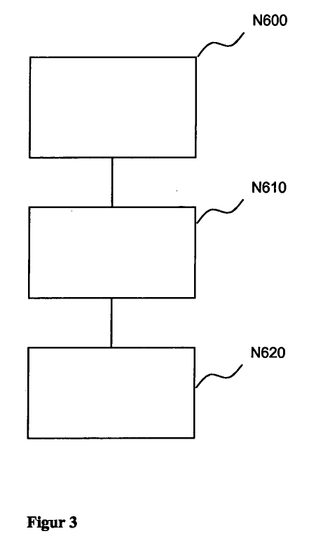

The basic idea of the example method for increasing the yield during manufacturing is described in FIG. 3. In a first step N600 (identification step), faulty execution units are identified. The first function of processing logic N520, and thus the test program, is used to perform the identification. The error information is stored in the second step N610 (storage step). Processing logic N520 provides the relevant information to memory element N530. In the third step N620 (configuration), switching circuit logic N510 uses the information from N530 and uses the first function of the switching circuit logic to configure the outputs of the execution units in accordance with the required activity and passivity. While this may indeed be carried out by software, in a preferred application, the configuration is not carried out by software control in this instance.

The main reason for inactivity is faultiness. In a preferred extension, however, other reasons may also be valid. Thus, for example, even execution units for completely error-free structural elements may possibly be marked as inactive in this memory element.

In particular, if the test runs not only at the end of the assembly line, but also in operation (for example, in an initialization phase or even during normal operation), it is possible to detect errors that arise, not during manufacturing, but rather in operation. Using the second function of the switching circuit logic (to link the active execution units to each other in operation) and the second function of the processing logic (carry out a comparison of the signals switched to an output) as shown in the description from FIG. 1, it is easily possible to detect errors even in operation and to identify faulty execution units.

If error-free execution units are marked as inactive, then it is possible to exchange a unit identified as faulty for an error-free but inactive unit when an error occurs in operation. To this end, preferably information indicating whether the execution unit is merely inactive or whether it is also faulty is stored in memory element N530. Advantageously, in operation, in the example embodiment, it is not possible to change the information indicating that a given execution unit is faulty.

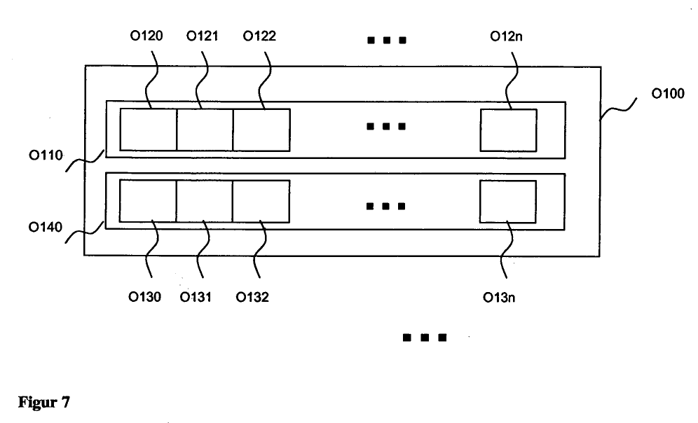

FIG. 7 describes an example structure for a memory element O100 (corresponds to N530). It contains a first memory area O110 in which memory locations O120 . . . , O12n exist, preferably in accordance with the number of execution units. Each memory location is implemented preferably via at least one bit. The number or address of the memory location O12i is uniquely linked to the number or identification of an execution unit. For example, a bit in O120 that is set to 0 indicates that the relevant execution unit is active. If it is set to 1, the relevant execution unit is inactive. This information may be contained in memory locations O120, . . . , O12n in an error-tolerant manner or linked to additional information; however, the fundamental informational content relating to this application always remains the same.

Optionally, a second memory area O140 may exist in addition, which contains memory locations O130, . . . , O13n, preferably in accordance with the number of execution units. Each memory location is implemented preferably via at least one bit. The number or address of memory location O13i is uniquely linked to the number or identification of an execution unit. For example, a bit in O130 that is set to 0 indicates that the relevant execution unit is error-free. If it is set to 1, this means that the relevant execution unit is faulty. This information may be contained in the memory locations O130, . . . , O13n in an error-tolerant manner or linked to additional information; however, the fundamental informational content relating to this application always remains the same. Optionally, it may be impossible to write to this memory area or it may be possible to write to it only under special circumstances or in a special way, so that it is ensured that an execution unit that has been marked as faulty is not mistakenly identified as error-free.

By using inactive but error-free execution units, it is possible to use the cold redundancy that this method provides for error-free structural elements for the purpose of increasing operational availability and reliability.

An additional possibility for using the present invention is to enable graceful degradation and limp home modes.

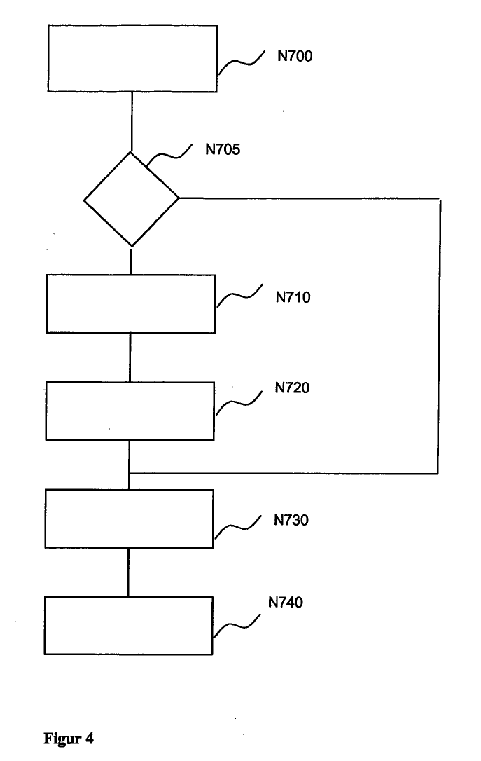

The premise here is that in operation an error was detected via the above-mentioned second function of the processing logic. FIG. 4 describes a method that is preferably used in this instance. First, in step N700 (error detection), an error is detected. This may be achieved by applying a test program, for example. However, if the system is in a compare mode, which may be set by the second functions of the processing logic and the switching circuit logic, for example, such an error-detection is also possible in normal operation, that is, the application software acts as a test program. This is particularly advantageous for two reasons: on the one hand, a dedicated test program is not required; on the other hand, all errors of the execution units that have any effect at all are detected in this way. In step N705 a check is done to see whether the existing configuration of switching circuit logic and processing logic is already able to identify a faulty execution unit. If this is the case, steps N710 (configuration for error detection) and N720 (identification step) are already complete, and a direct transition is made to step N730. This is the case, for example, if the error occurs in a subsystem in which the signals from three execution units are compared. If this (in step N705) is not the case (for example, if an error is detected in a subsystem of two execution units that are running in a compare mode), then in step N710 a configuration must first be selected that permits an error identification. For example, the simplest way to achieve this is for the “suspect candidates” (that is, all execution units that participate in a subsystem that has generated an error) to be combined with a sufficient number of other execution units by switching circuit logic N510 to result in an output signal. Preferably, the software part that revealed the error is reused as a test program; however, a dedicated test program may also be used. The first function of the processing logic then permits the execution of step N720 and the identification of the faulty execution unit. However, alternatively another method for identification may also be selected. For example, it is possible to couple one of the suspect candidates with another error-free execution unit. If no error is identified, then another execution unit is faulty. If an error is identified, then it is possible to conclude that an error exists in this execution unit. While the identification provided by the latter method is not as reliable, it is easier to implement it in operation. It would thus be advantageous if a motor vehicle was performing a critical driving maneuver that is influenced by the structural element, for example. Once the faulty execution unit has been identified, the two steps N730 (storage step, corresponds to N610) and N740 (configuration, corresponds to N620) run.

The example method according to the present invention now provides multiple advantageous options for this last step.

If there is a sufficient number of error-free but inactive execution units, it is possible to restore a fully functional system, as described above.

If there are too few error-free execution units for normal operation, one may run the existing software as well as possible on the existing execution units. This is advantageous particularly if the system is normally specified with runtime reserves. If this is the case, then it is likely that even a reduced number of execution units provides sufficient performance to allow for the operation. On the system level, this may be supported in particular by avoiding particularly performance-intensive operating states (for example, high rotational frequencies in the engine of a motor vehicle).

If there are too few error-free execution units for normal operation, it is alternatively possible to allow only a subset of the application to run.

If there are too few error-free execution units for normal operation, in a third option it is possible to allow the application to run in other modes. For example, it is possible to do without a strong compare mode and to use only a weaker compare mode or a performance mode. Although in this case only a weaker error detection or error tolerance is provided for the subsequent operation, this may possibly be tolerated since this state possibly must be maintained only for a limited time. This option is particularly easily implemented in this invention, since only the components and methods presented here must be used. Combinations of these variants are, of course, likewise conceivable.

A fundamentally different possibility for using the idea of the present invention is to omit the memory element and to use other means to deactivate potentially faulty execution units in such a way that they are deactivated reliably and irreversibly. This may be achieved by influencing (for example, by separating or connecting) lines in the structural element.

Different options include:

The use of antifuses for dedicated lines (this may be used in operation, in maintenance, in assembly, or during manufacture), mechanical treatment (soldering, separation) of lines, burning with lasers, electron radiation, x-ray radiation, or special electrical signals and chemical influence on the lines.

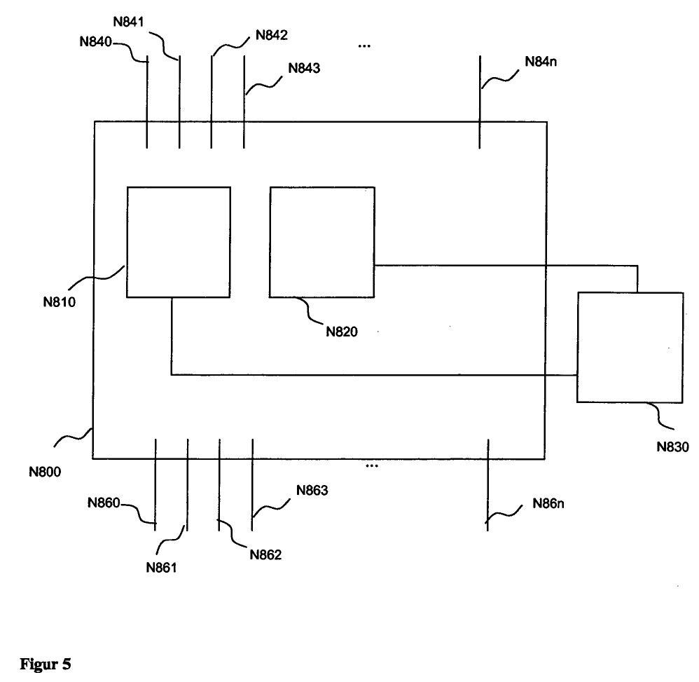

To this end, an influencing component may be necessary instead of the memory element. FIG. 5 shows the function of this influencing component. In FIG. 5, elements N810, N820, N84i, N86i of switchover and compare unit N800 have the same functions as elements N110, N120, N14i, N16i of switchover and compare unit N100 in FIG. 1. In addition, an influencing component N830 is shown. Processing logic N820 sends the information about the execution units identified as faulty to influencing component N830. The latter has elements, as listed above, for example, for influencing lines or functional groups in the structural element such that execution units are deactivated. N830 may be a component within the structural element, the control device, or the system; N830 may also be a machine in the manufacturing process or a human operator of such a machine. It is also possible for this component to be used in maintenance. Optionally, the relevant information may also be provided to the switching circuit logic, so that the latter performs the first function such that the elements identified as inactive by N830 actually become inactive.

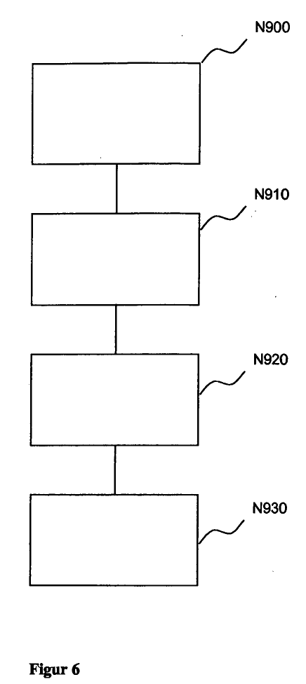

One basic idea of the example method for increasing the yield by using influencing component N830 is described in FIG. 6. In a first step N900 (identification step), faulty execution units are identified. The first function of processing logic N820, and thus the test program, is used to perform the identification. In second step N910, the error information is transmitted from processing logic N820 to influencing component N830. In the third step N920, influencing component N830 uses this information to influence, through the components available to it, the lines or functional groups in the structural element such that the faulty components are inactive. In the optional fourth step N930, switching circuit logic N810 uses the information and uses the first function of the switching circuit logic to configure the outputs of the execution units in accordance with the required activity and passivity.

Of course, such an influencing component may also be used in operation. All advantages that apply in the use of a memory element are applicable in this instance also, since the effect on the system is the same. However, in this instance it is advantageous if the influencing component exists as a hardware component in the system.

Apart from being applied to the execution units mentioned in the description of the exemplary embodiments, the advantageous example methods and devices may also be applied to additional components of a semiconductor circuit, such as analog/digital converters, timer components, interrupt controllers, communication controllers, or control units, for example. In the following, these components of a semiconductor circuit are grouped together in their entirety under the term functional units.

In an additional preferred exemplary embodiment, the present invention described here is used together with an ECC protection for other memory elements. In this case, a highly available structural element is produced, in which both memories and execution units are configured in an error-tolerant way and thus make it possible both to maximize the yield and to guarantee an optimal availability in operation.

1-28. (canceled)

29. A method for configuring a semiconductor circuit having at least two identical or similar functional units, comprising:
identifying and deactivating a faulty one of the at least two identical or similar functional units in the event of an error in at least one of the identical or similar functional units.

30. The method as recited in claim 29, wherein the configuration of the semiconductor circuit takes place as a process step of a manufacturing, test, diagnosis, or maintenance process.

31. The method as recited in claim 29, wherein in each case, at least two of the identical or similar functional units of the semiconductor circuit are able to be switched into an operating mode in which the identical or similar functional units execute identical functions, instructions, program segments, or programs, and a comparison of the output signals of the identical or similar functional units to each other is possible.

32. The method as recited in claim 29, further comprising:
comparing output signals of the functional units to reference values to identify faulty functional units.

33. The method as recited in claim 31, wherein at least one of: i) initiation of the switchover, ii) the comparing of the output signals of the functional units to each other, and iii) comparing of the output signals to reference values, may be executed by one of an external manufacturing device, test device, or diagnosis device that is not part of the semiconductor circuit.

34. The method as recited in claim 29, further comprising:
forming at least one of a configuration status and an error status for at least the functional units of the semiconductor circuit that are identified as faulty.

35. The method as recited in claim 34, wherein the deactivating includes storing information about the at least one of the configuration status and the error status of the faulty functional unit in a memory device such that the information may be read out when the semiconductor system is being at least one of initialized and operated, and the stored information is processed such that a use of the faulty unit in operation is not allowed.

36. The method as recited in claim 35, wherein one of an external manufacturing device, a test device, or a diagnosis device that is not part of the semiconductor circuit is used to ascertain or store in a memory device the at least one of the configuration status and the error status of at least one functional unit of the semiconductor circuit.

37. The method as recited in claim 29, wherein a faulty unit is irreversibly deactivated.

38. The method as recited in claim 37, wherein electric connections to or between functional units of the semiconductor circuit are interrupted to deactivate the faulty unit.

39. The method as recited in claim 38, wherein the electrical connections on the semiconductor circuit are interrupted by mechanical action on the semiconductor circuit.

40. The method as recited in claim 38, wherein the electrical connections on the semiconductor circuit are interrupted by chemical action on the semiconductor circuit.

41. The method as recited in claim 38, wherein the electrical connections on the semiconductor circuit are interrupted by optical action on the semiconductor circuit.

42. The method as recited in claim 38, wherein the electrical connections on the semiconductor circuit are interrupted by electric action on the semiconductor circuit.

43. The method as recited in claim 37, wherein the faulty unit is deactivated by one of an external manufacturing device, a test device, or a diagnosis device.

44. A device for configuring a semiconductor circuit having at least two identical or similar functional units, comprising:
an arrangement adapted to identify an error in at least one of the identical or similar functional units and to deactivate a faulty one of the identical or similar functional units if an error is identified.

45. The device as recited in claim 44, further comprising:
a switchover device with which at least two of the identical or similar functional units of the semiconductor circuit may be switched over into an operating mode in which the at least two of the identical or similar functional units execute identical functions, instructions, program segments, or programs.

46. The device as recited in claim 44, further comprising:
a comparitor adapted to compare output signals of at least two of the identical or similar functional units to each other.

47. The device as recited in claim 44, further comprising:
a comparitor adapted to compare output signals of at least one functional unit to reference values.

48. The device as recited in claim 44, further comprising:
a storage device adapted to store reference values for identifying faulty functional units.

49. The device as recited in claim 46, wherein the comparitor is at least partially on the semiconductor circuit.

50. The device as recited in claim 44, further comprising:
a receiver on the semiconductor circuit with which signals from one of a manufacturing device, a test device, a diagnosis device, or a maintenance device may be received.

51. The device as recited in claim 47, wherein the comparitor is at least partially on the semiconductor circuit.

52. The device as recited in claim 48, wherein the storage device is at least partially on the semiconductor circuit.

53. The device as recited in claim 44, further comprising:
a storage device adapted to store at least one item of information about one of a configuration status or error status of functional units in such a way that the one of the configuration status or error status may be read out when the semiconductor system is being at least one of initialized or operated.

54. The device as recited in claim 53, further comprising:
an element adapted to read out and process memory information and as a function of the memory information, permit or prevent in operation a use of a faulty unit.

55. The device as recited in claim 53, wherein the storage device is a non-volatile storage device.

56. The device as recited in claim 53, wherein the memory device is adapted so that a write access to the memory device may be carried out only by one of a manufacturing device, test device, diagnosis device, and maintenance device that is not installed on the semiconductor circuit.

57. The device as recited in claim 44, further comprising:
a switchover device adapted to reversibly deactivate a functional unit, the switchover device being a part of the semiconductor circuit or part of a structural element on which the semiconductor circuit is implemented.

58. The device as recited in claim 44, further comprising:
a switchover device adapted to irreversibly deactivate a faulty functional unit.
